(19) United States
(12) Patent Application Publication
(10) Pub. No.: US 2015/0092322 A1
(43) Pub. Date: Apr. 2, 2015

(54) POWER SUPPLY UNIT

(71) Applicant: Hon Hai Precision Industry Co., Ltd., New Taipei (TW)

(72) Inventor: CHIEN-TSUNG YEN, New Taipei (TW)

(73) Assignee: HON HAI PRECISION INDUSTRY CO., LTD., New Taipei (TW)

(21) Appl. No.: 14/067,971

(22) Filed: Oct. 31, 2013

(30) Foreign Application Priority Data
Sep. 30, 2013 (TW) 102135425

(51) Int. Cl. H05K 5/02; H02B 1/46

(52) U.S. Cl. CPC H05K 5/0221; H02B 1/46
USPC 361/679.01

(57) ABSTRACT

A power supply unit includes a shell receiving a power supply with a socket, a rotating member, and a resilient hook. A first end of the rotating member is rotatably connected to a first side of the shell, the hook is mounted to a second side of the shell opposite to the rotating member, and a second end of the rotating member opposite to the first end is detachably latched to the hook. The rotating member further includes an abutting plate adjacent to the socket. A plug is plugged into the socket. The rotating member is rotated toward the shell, until the hook latches with the rotating member. The plug abuts the abutting plate.

### BACKGROUND

1. Technical Field

The present disclosure relates to a power supply unit.

2. Description of Related Art

Plugs are connected to power supplies for powering electronic devices. However, plugs may disengage from power supplies accidentally, and it is inconvenient and troublesome to reconnect the plugs.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a power supply unit.

FIG. 2 is an assembled, isometric view the power supply unit of FIG. 1.

FIG. 3 is similar to FIG. 2, but shows the power supply unit in use.

FIG. 4 shows a cutaway view of the power supply unit taken along line IV-IV of FIG. 3.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

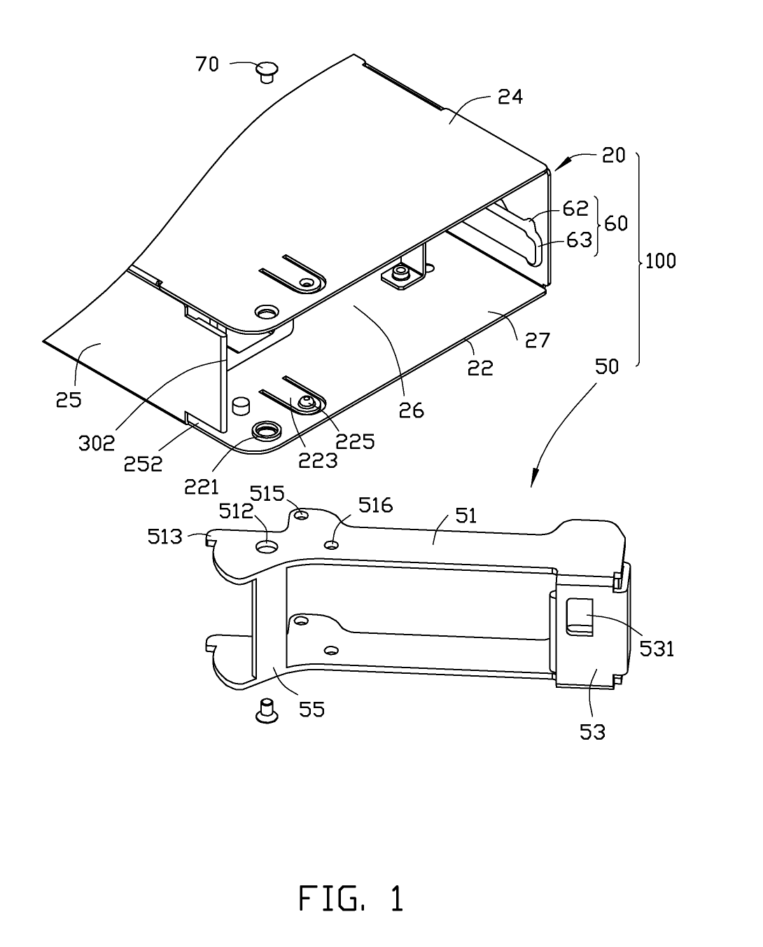

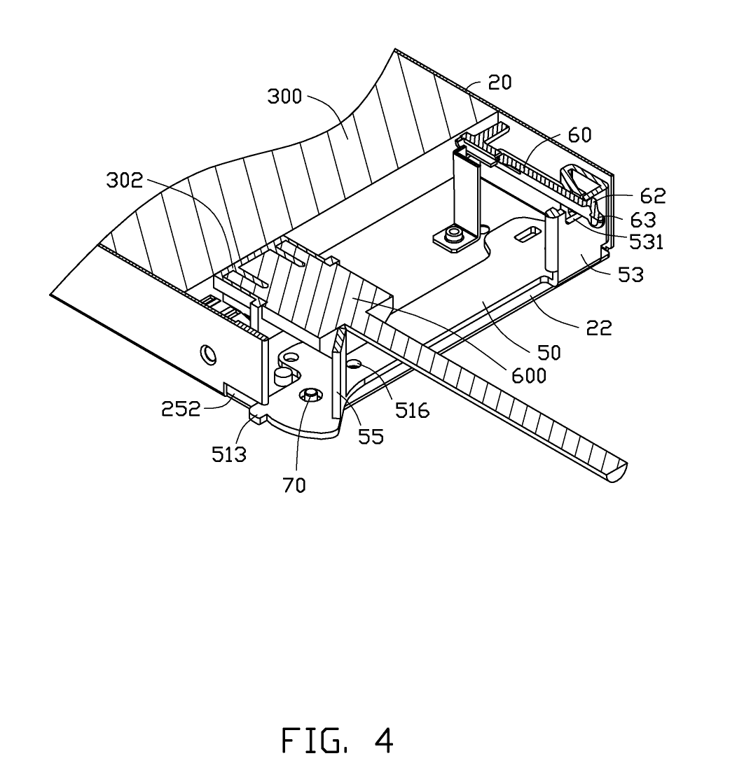

FIG. 1 shows an embodiment of a power supply unit 100. The power supply unit 100 includes a shell 20 receiving a power supply 300 (shown in FIG. 4), a rotating member 50, a resilient hook 60, and two shafts 70. The power supply 300 includes a socket 302 located at a rear end of the power supply 300.

The shell 20 includes a bottom wall 22, a top wall 24 opposite to the bottom wall 22, and two opposite sidewalls 25 connected substantially perpendicularly between the bottom wall 22 and the top wall 24. The bottom wall 22, the top wall 24, and the sidewalls 25 cooperatively define a receiving space 26. A rear end of the shell 20 defines an opening 27 communicating with the receiving space 26. The power supply 300 is received in the receiving space 26, and the socket 302 faces the opening 27. A rear end of the sidewall 25 adjacent to the socket 302 defines two through slots 252 adjacent to the bottom wall 22 and the top wall 24, respectively. A shaft hole 221 is defined in the bottom wall 22 and the top wall 24 adjacent to the sidewall 25 defining the through slots 252. The two shaft holes 221 face each other. A resilient tongue 223 is formed adjacent to each shaft hole 221, and the two resilient tongues 223 face each other. A hemispherical positioning block 225 is formed on a distal end of each tongue 223 and protrudes into the receiving space 26.

The hook 60 is mounted on an inner surface of the sidewall 25 opposite to the sidewall 25 defining the through slots 252. The hook 60 includes a latching portion 62 and an operation portion 63.

The rotating member 50 includes two oppositely-facing rotating plates 51, a latching plate 53 connected between first ends of the rotating plates 51, and an abutting plate 55 connected between second ends of the rotating plates 51. Each rotating plate 51 defines a through hole 512 adjacent to the abutting plate 55, and the two through holes 512 face each other. A latching piece 513 protrudes out from the second end of each rotating plate 51. Each rotating plate 51 defines a first positioning hole 515 and a second positioning hole 516, both adjacent to the corresponding through hole 512. A middle part of the latching plate 53 defines a latching hole 531.

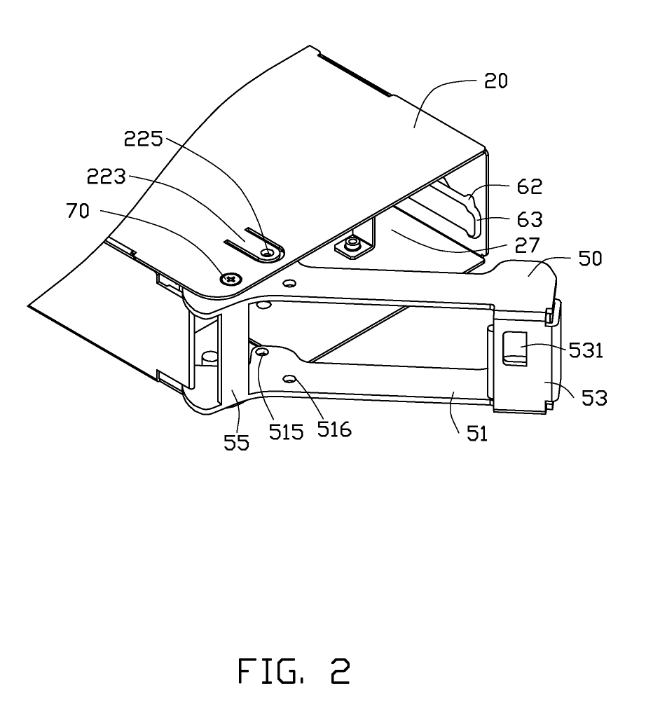

FIG. 2 shows that in assembly of the power supply unit 100, the rotating member 50 is received in the opening 27, such that the through holes 512 of the rotating member 50 align with the shaft holes 221 of the shell 20, and the latching pieces 513 are received in the through slots 252 of the shell 20. The positioning blocks 225 of the tongues 223 are received in the first positioning holes 515 of the rotating member 50. The two shafts 70 are correspondingly received through the shaft holes 221 and the through holes 512. Thus, the rotating member 50 is rotatable about the shafts 70.

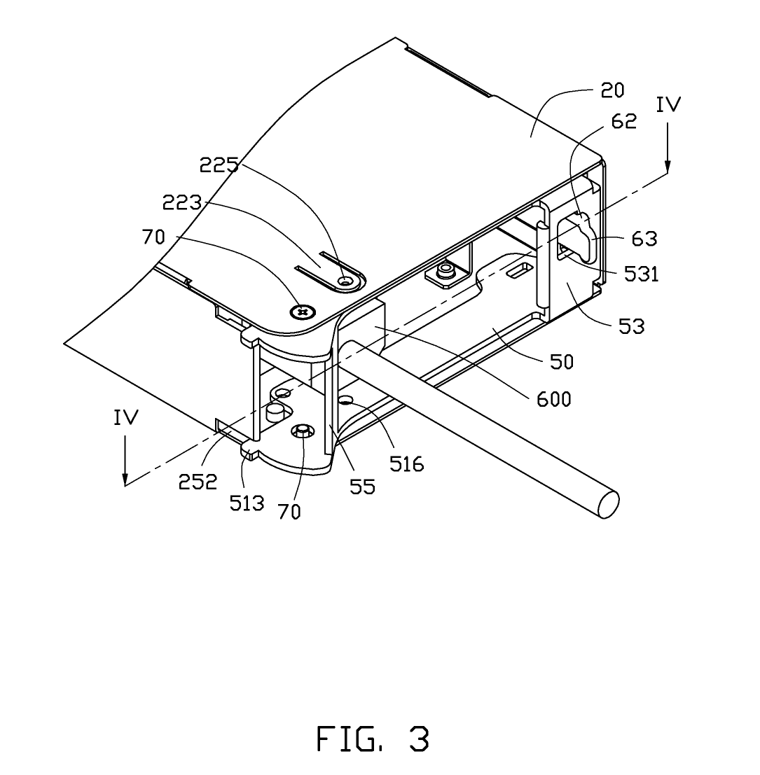

FIG. 3 and FIG. 4 show the power supply unit 100 in use. A plug 600 extends through a space defined between the rotating plates 51 of the rotating member 50, to be plugged into the socket 302 of the power supply 300. The rotating member 50 is rotated toward the shell 20. As the rotating member 50 rotates, the positioning blocks 225 are forced out of the first positioning holes 515, and the tongues 223 are resiliently pushed away from each other. The rotating member 50 is further rotated toward the shell 20, such that a side wall of the latching plate 53 bounding the latching hole 531 resiliently deforms the hook 60. The latching portion 62 and the operation portion 63 of the hook 60 pass through the latching hole 531, and the hook 60 restores to latch the latching portion 62 with the latching plate 53. When the rotating member is rotated until the positioning blocks 225 are aligned with the second positioning holes 516, the tongues 223 are restored, and the positioning blocks 225 are received in the second positioning holes 516 of the rotating member 50. The abutting plate 55 abuts a rear end of the plug 600 to prevent the plug 600 from disengaging from the socket 302 of the power supply 300. The latching pieces 513 of the rotating member 50 help latch the rotating member 50 to the shell 20.

To pull the plug 600 from the socket 302, the operation portion 63 is manually pressed to deform the hook 60, until the latching portion 62 disengages from the latching plate 53. The rotating member 50 is rotated away from the shell 20 to rotate the abutting plate 55 away from the plug 600. Thus, the plug 600 is easily pulled from the socket 302.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A power supply unit, comprising:
a shell;
a power supply received in the shell, and comprising a socket;
a resilient hook mounted to a first side of the shell;
a rotating member comprising a first end rotatably connected to a second side of the shell, a second end detachably latched to the hook, an abutting plate to abut against a plug plugged to the socket of the power supply in response to the second end of the rotating member latching to the hook.

2. The power supply unit of claim 1, wherein the shell comprises a bottom wall, a top wall, and two sidewalls connected between first and second sides of the bottom wall and the top wall, the bottom wall, the top wall, and the sidewalls cooperatively bound a receiving space accommodating the power supply, a rear end of the shell defines an opening communicating with the receiving space, the socket faces the opening, the first end of the rotating member is rotatably connected between the bottom wall and the top wall adjacent to the sidewall of the shell at the first side, the hook is installed to the other sidewall of the shell at the second side.

3. The power supply unit of claim 2, wherein the rotating member comprises two opposite and spaced rotating plates and a latching plate connected between first ends of the rotating plates, the abutting plate is connected between second ends of the rotating plates opposite to the latching plate, the hook is detachably latched to the latching plate.

4. The power supply unit of claim 3, wherein the bottom wall and the top wall define two opposite shaft holes adjacent to the socket of the power supply, the rotating plates define two though holes aligning with the shaft holes, two shafts are extended through the shaft holes to engage in the through holes.

5. The power supply unit of claim 4, wherein the bottom wall forms a resilient tongue, a hemispherical positioning block extends toward the receiving space from a distal end of the tongue, the rotating plate adjacent to the bottom wall of the shell defines a first positioning hole and a second positioning hole, when the positioning block latches in the first positioning hole, the latching plate is away from the hook, and when the positioning block latches in the second positioning hole, the hook latches to the latching plate and the abutting plate abuts against the plug.

6. The power supply unit of claim 3, wherein the latching plate defines a latching hole, the hook is latched in the latching hole of the latching plate.

7. The power supply unit of claim 6, wherein the hook comprises a latching portion latching in the latching hole, and an operation portion facilitating deforming the hook to disengage from the latching hole.

8. The power supply unit of claim 3, wherein a latching piece protrudes out from the first end of the rotating member, the latching piece extends through the shell.
